(19) United States
(12) Patent Application Publication
(10) Pub. No.: US 2006/0141153 A1
(43) Pub. Date: Jun. 29, 2006

(54) Method for making carbon nanotubes

(75) Inventors: Tadahiro Kubota, Saitama (JP); Nariaki Kuriyama, Saitama (JP); Jun Sasahara, Saitama (JP); Toshifumi Suzuki, Tokyo (JP)

Correspondence Address: Lumen Intellectual Property Services Inc, 2nd Floor, 2345 Yale Street, Palo Alto, CA, 94306, US

(73) Assignee: Honda Giken Kogyo Kabushiki Kaisha, Tokyo (JP)

(21) Appl. No.: 10/520,242

(22) PCT Filed: May 2, 2003
(86) PCT No.: PCT/JP03/05628

§ 371 Date: Jun. 10, 2005

(30) Foreign Application Priority Data
Jun. 24, 2002 (JP) 2002-182468

(51) Int. Cl. C23C 16/00; D01F 9/12

(52) U.S. Cl. 427/249.1; 423/447.3

(57) ABSTRACT

A method for forming a carbon nanotube (5) on an electroconductive member (2). A catalytic layer (3) including a metal or alloy that serves as a catalyst for growing the carbon nanotube is formed on an electroconductive member, the metal or alloy of the catalytic layer is processed so as to turn it into small particles (3a) by heating the catalytic layer formed on the electroconductive member to a prescribed temperature while supplying inert gas, and a carbon nanotube is grown on the electroconductive member by using the small particles of the metal or alloy of the catalytic layer as a catalyst. The fine metallic particles that can be used as a catalyst for growing the carbon nanotube can be prepared in a simple, economical and efficient manner. The carbon nanotube is highly suitable for use as the diffusion layer of a fuel cell.

### FIELD OF THE INVENTION

The present invention generally relates to carbon films that are used in small fuel cells, and in particular to a method for forming a carbon nanotube (CNT) on an electroconductive member.

### DESCRIPTION OF THE RELATED ART

A carbon nanotube consists of a cylindrical tube made of carbon and is provided with a diameter in the order of nanometers owing to certain desirable properties thereof. As a carbon nanotube is highly porous, it can serve as a gas diffusion layer. Japanese patent laid open publication No. 2000-141084, for instance, discloses the use of carbon film consisting of a carbon nanotube as a carrier for platinum or other catalyst. The carbon nanotube film is formed on an iron or nickel film, which, in turn, is formed on an electrode terminal layer made of gold or the like. A platinum catalyst is sputtered onto the surface of the carbon nanotube film.

There are other methods for forming a carbon nanotube using electric arc discharge and heating. Japanese patent laid open publication No. 2001-58805, for instance, discloses a method for making carbon nanotubes in a large volume by mixing fullerene molecules with a transition element or with an alloy containing a transition element, and heating the mixture on a ceramic board. It is known to use a transition metal such as iron and nickel in a fine particle form as a catalyst for forming a carbon nanotube. Such fine metallic particles can be prepared by etching metallic film using laser or microwave and filling metallic film into the pores of zeolite and porous silicon. This publication does not mention forming a carbon nanotube on an electroconductive member.

By depositing metal nanoparticles on a substrate or impregnating the substrate into solution of metal, many carbon nanotubes can grow randomly from the catalytic particles formed on the substrate. However, this random growth results in some nanotubes sticking together, affecting the properties of the carbon film. In “The Formation Conditions of Carbon Nanotubes Array Based on FeNi Alloy Island Films,” Thin Solid Films 339 (1999) pp. 6-9, X. H. Chen et al. disclose a method to prepare aligned, isolated carbon nanotube films on a conducting sustrate based on chemical vapor deposition (CVD) catalyzed by FeNi alloy islands sputtered onto Ag film. X. H. Chen et al. specifically teach that if the FeNi alloy film is a continuous film before heat treatment, the size of the alloy particles after heat treatment is too large and not uniform. If the catalytic particles are too large, the carbon nanotubes are not able to form through.

### BRIEF SUMMARY OF THE INVENTION

A primary object of the present invention is to provide an improved method for forming a carbon nanotube on an electroconductive member.

A second object of the present invention is to provide a method for forming a carbon nanotube which allows fine metallic particles that can be used as a catalyst for growing a carbon nanotube to be prepared in a simple, economical and efficient manner.

A third object of the present invention is to provide a method for forming a carbon nanotube which is suitable for use in fuel cells.

The present invention accomplishes such objects by providing a method for making a carbon nanotube (5) on an electroconductive member (2), comprising the steps of:
forming a catalytic layer (3) including a metal or alloy that serves as a catalyst for growing a carbon nanotube on the electroconductive member;
processing the metal or alloy of the catalytic layer so as to turn it into small particles (3a); and
growing a carbon nanotube on the electroconductive member by using the small particles of the metal or alloy of the catalytic layer as a catalyst; wherein the step of processing the metal or alloy of the catalytic layer so as to turn it into small particles comprises the step of heating the catalytic layer formed on the electroconductive member to a prescribed temperature while supplying inert gas.

As such, fine metallic or alloy particles that can be used as a catalyst for growing a carbon nanotube can be prepared in a simple, economical and efficient manner. Moreover, by using the electroconductive member as a catalyst, a carbon nanotube can be efficiently formed thereon.

The catalytic layer may comprise a member selected from a group consisting of Fe, Ni, Co, Mo, and an alloy thereof. The electroconductive member may comprise at least one material selected from a group consisting of Ti, Au, Ni, Co, Cu, Al, Mo, W and Ta. The inert gas may consist of helium or argon.

The prescribed temperature may be in range of 0.49 Tm to 0.59 Tm where Tm is the melting point of the metal or alloy of the catalytic layer in Kelvin. When the catalytic layer is made of iron, the prescribed temperature may be approximately 700° C. If the heating temperature is higher or lower than this, the particles tend to become coarser, and a desired particle size cannot be obtained.

The small particles of the metal or alloy preferably have a particle size of 0.5 to 50 nm. Particles of such a size provides an adequate catalytic action in forming a carbon nanotube, and can be easily obtained by the method described above. By turning the metal or alloy of the catalytic layer into small particles at such a heating temperature, particles of a desired size can be obtained both easily and efficiently.

The step of growing the carbon nanotube may comprise the step of supplying mixed gas containing hydrocarbon gas and the inert gas at a ratio of 1:2 to 1:50 so that amorphous carbon other than a carbon nanotube or soot may be avoided and a carbon nanotube may be formed in an efficient manner without the growth rate thereof being hampered to any great extent.

The step of supplying the mixed gas may be conducted at a flow rate of 1 to 100 cm/min, and more preferably at a flow rate of approximately 30 cm/min. Thereby, the productivity can be improved by controlling the formation of soot and reducing the amount of the material gas that is expelled without contributing to the formation of the carbon nanotube. In embodiments where the step of growing the carbon nanotube comprises the step of placing the electroconductive member including the small particles of the metal or alloy in a tube having an inner diameter of approximately 30 mm, the flow rate of the mixed gas that is flowed substantially along the length of the tube is preferably in the order of 200 to 300 sccm (standard cubic centimeter per minute).

The electroconductive member may be deposited on an inorganic substrate made of such material as silicon or glass. The electroconductive member may have a two-layered structure including a titanium (Ti) layer and a tungsten (W) layer formed thereon. Instead of titanium, aluminum (Al), nickel (Ni) or chromium (Cr) can also be used. Instead of tungsten, molybdenum (Mo) or tantalum (Ta) can also be used.

### BRIEF DESCRIPTION OF THE DRAWINGS

Now the present invention is described in the following with reference to the appended drawings, in which:

FIG. 1 is a flowchart describing the preferred embodiment of the method for forming a carbon nanotube film according to the present invention;

FIGS. 2a to 2e are schematic sectional views illustrating an exemplary method for forming a carbon nanotube film according to the present invention;

FIG. 3 is a schematic sectional view of the device for forming a carbon nanotube film that can be used for implementing the present invention;

FIG. 4a to 4e are schematic sectional views illustrating another exemplary method for forming a carbon nanotube film according to the present invention; and

FIGS. 5a to 5c are photographs showing the states of iron particles for different processing temperatures.

### DETAILED DESCRIPTION OF THE PREFERRED EMBODIMENTS

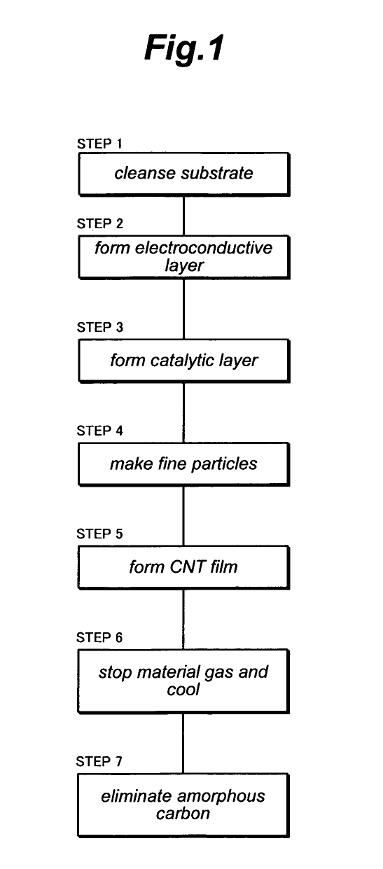

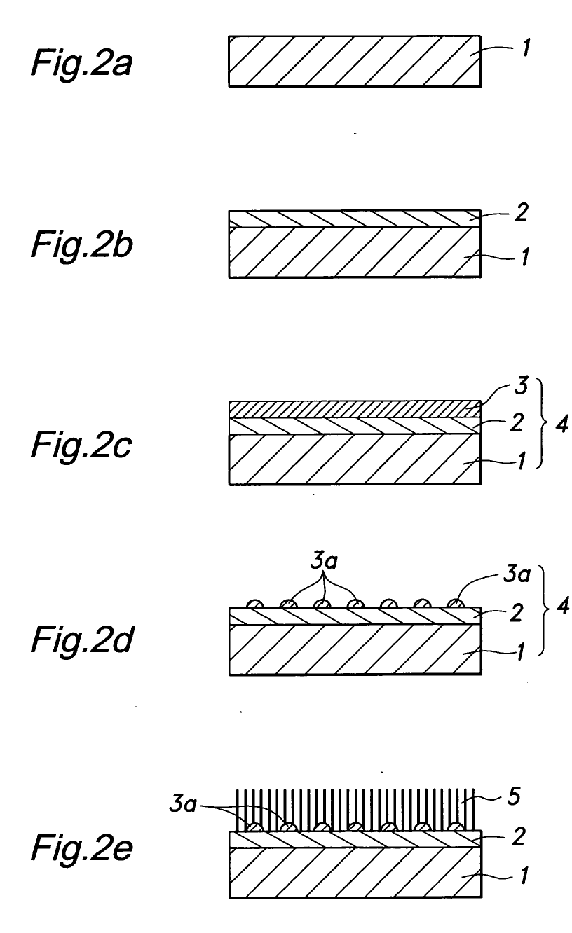

FIG. 1 is a flowchart of a preferred embodiment of the method of present invention for forming a carbon nanotube, and FIG. 2 includes several views showing the states in the various steps of the flowchart of FIG. 1.

In step 1, an inorganic substrate 1 typically consisting of silicon or glass is cleansed (FIG. 2a).

In step 2, an electroconductive layer 2 is deposited onto the inorganic substrate 1. In some embodiments, the electroconductive layer 2 consists of a metal, such as titanium (Ti), gold (Au), nickel (Ni), cobalt (Co), copper (Cu), aluminum (Al), molybdenum (Mo), tungsten (W), tantalum (Ta), or doped semiconductor material, for instance, by vapor deposition using a resistive heater or sputtering (FIG. 2b).

In embodiments where the inorganic substrate 1 consists of silicon, it is preferable to form an electroconductive layer 2 consisting of a two-layered structure including a titanium (Ti) layer formed over the substrate and a tungsten (W) layer formed on the titanium layer. Tungsten is preferred because it has a high melting point and is therefore resistant to the influences of the subsequent thermal processes. Titanium improves the contact between the tungsten layer and substrate, and may be substituted by nickel (Ni), aluminum (Al) or chromium (Cr). Tungsten may be substituted by molybdenum (Mo) or tantalum (Ta).

In embodiments where the inorganic substrate 1 consists of conductive silicon (for instance, doped silicon), it can be advantageously used for conducting electricity to an external circuit.

In step 3, a catalytic layer 3 consisting of a transition metal such as iron (Fe) and capable of a catalytic action for growing a carbon nanotube film is formed on the electroconductive layer 2 (FIG. 2c). This can be accomplished by using electron beam vapor deposition. Iron may be substituted by nickel (Ni), cobalt (Co) or molybdenum (Mo). Alternatively, two or more members of a group consisting of iron, nickel, cobalt and molybdenum, or an alloy of such metals can also be used. This combination of the electroconductive layer 2 and catalytic layer 3 formed on the substrate 1 is referred to as an assembly 4 hereinafter.

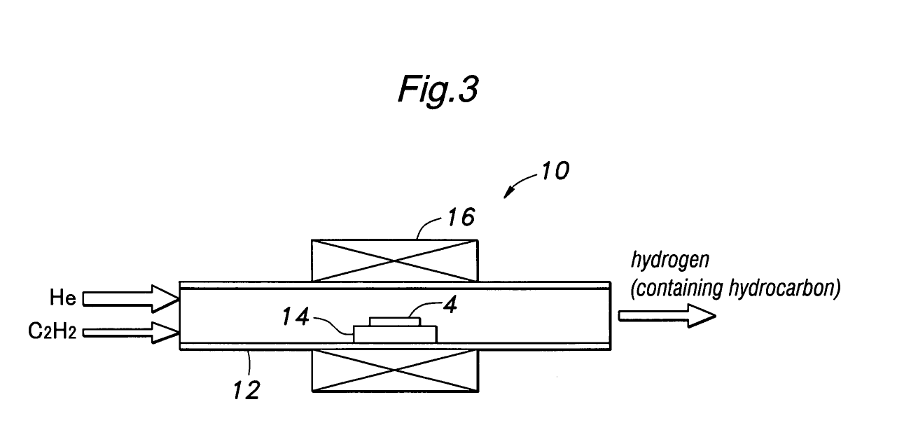

FIG. 3 is a schematic longitudinal sectional view of a preferred device 10 for forming a carbon nanotube on the electroconductive layer 2 by suitably processing the assembly 4 obtained in step 3. This device 10 comprises a quartz tube 12 defining an inner bore 30 mm in inner diameter for conducting desired gas along the length thereof. A quartz holder 14 is provided inside this tube 12 for holding the assembly 4 to be processed. The quartz tube 12 is placed in an electric furnace 16 so as to be heated to a desired temperature.

Referring to FIG. 1 once again, according to the present invention, in step 4, the assembly 4 is secured to the quartz holder 14 in the quartz tube 12, and is heated for a prescribed period of time by suitably adjusting the temperature of the electric furnace 16 while inert gas such as helium and argon is conducted through the quartz tube 12 from an end (left end in FIG. 3) thereof at a prescribed velocity. As a result, the metal or alloy of the catalytic layer 3 on the surface of the assembly 4 is turned into fine particles so that a large number of fine particles of the metal or alloy 3a can be obtained (FIG. 2d). By thus processing the catalytic layer 3, and obtaining a large number of catalytic particles, the catalytic action during the process of growing the carbon nanotube can be enhanced.

If the particles are not fine enough, the direction of the growth of the carbon nanotube may become uneven, and this prevents the formation of a clean film. When forming fine particles of metal or alloy for the catalytic layer 3 by heating and supplying inert gas at the same time, the particles can be made finer as the heating temperature is increased.

A particle size below 50 nm is preferred. However, if the particle size is smaller than 0.5 nm, the aggregating force of the particles becomes so strong that the size of the particles in the aggregated parts thereof may become even greater, and it becomes difficult to control the particle size below 0.5 nm and make the particle size uniform at the same time. This leads to a reduction in productivity. Therefore, the particle size is preferred to be between 0.5 nm and 50 nm. The process of preparing the metallic or alloy particles for the catalytic layer 3 described above will be referred to as “preprocessing” hereinafter. The preprocessing according to the present invention solves the prior art problem regarding using a continuous film as the catalytic layer 3.

The optimum heating temperature in the preprocessing may vary depending on the kind of metal or alloy that is used in the catalytic layer 3. As will be discussed in connection with the preferred embodiments, when the catalytic layer 3 is made of iron (Fe), the optimum heating temperature would be approximately 700° C. (973° K.). This temperature in absolute (Kelvin) temperature is approximately 0.54 times the melting point of iron or 1808° K. (1536° C.), and is substantially equal to the temperature from which the atoms become able to move freely in solid (first recrystallization temperature). Thus, the optimum heating temperature for turning the metal or alloy for the catalytic layer into fine particles is in the vicinity of 0.54 Tm (0.54 Tm±0.05 Tm), where Tm is the melting point of the metal or alloy in absolute temperature.

When the preprocessing is concluded, in step 5, the flow rate of the inert gas is reduced, and material gas (hydrocarbon gas) such as acetylene, methane and ethylene is introduced into the tube at a prescribed flow rate. This causes a carbon nanotube having a diameter in the range of 0.5 to 100 nm to grow on the electroconductive layer 2, for instance, in the form of a carbon nanotube film 5 having a thickness in the range of 0.01 μm to 300 μm (FIG. 2e).

The produced carbon nanotube film 5 is generally oriented perpendicularly with respect to the assembly 4 or the substrate 1, and demonstrates a favorable electroconductivity in this direction. The material gas generates hydrogen as the carbon nanotube is produced, and the hydrogen along with the excess gas (hydrocarbon) that was not used is expelled from the other end (right end in FIG. 3) of the quartz tube 12.

During the process of forming the carbon nanotube, if the flow rate of the material gas is excessive, amorphous carbon other than carbon nanotube or soot is produced. This prevents the growth of the carbon nanotube resulting in a reduction of the content of the carbon nanotube in the film 5. Conversely, if the flow rate of the material gas is inadequate, the growth of the carbon nanotube is reduced resulting in a poor productivity. The flow rate ratio of the material gas to the carrier gas (inert gas) is preferably from ½ to 1/50, and more preferably approximately 1/10.

The flow velocity of the mixed gas consisting of the inert gas and material gas along the surface of the assembly 4 also affects the formation of the carbon nanotube film 5. If the flow velocity is too small, soot is actively produced and the content of the carbon nanotube in the film 5 decreases. If the flow velocity is excessive, much of the material gas is expelled without contributing to the formation of the carbon nanotube, and the productivity is impaired. A flow rate in the range of 1 cm/minute to 100 cm/minute is preferred, and a flow rate in the range of 30 cm/minute to 40 cm/minute (corresponding to approximately 200 to 300 sccm when the inner diameter of the tube is 30 mm) is particularly preferred. A flow rate of approximately 30 cm/minute (corresponding to approximately 200 sccm when the inner diameter of the tube is 30 mm) is most preferred.

During the process of forming the film, by keeping the flow rate of the material gas and carrier gas (inert gas) constant, the carbon nanotube can be made to grow vertically with respect to the substrate. By slightly varying the flow rate, the carbon nanotube can be made to grow in a curved manner. Curving the carbon nanotube promotes the entangling of the carbon nanotube fibers, and this in turn increases the firmness of the carbon nanotube film 5 and develops electroconductivity in lateral directions.

When the formation of the film is concluded, in step 6, the introduction of the material gas is terminated and the assembly is allowed to cool to the room temperature by continuing the flow of the inert gas. In step 7, the assembly 4 having the carbon nanotube film 5 formed thereon is removed from the electric furnace 16 and is processed by a high temperature in the atmosphere so that the amorphous carbon and the part of the carbon nanotube containing a large number of defects are selectively eliminated by oxidization and numerous gaps is produced in the carbon nanotube film 5. The part of the carbon nanotube having a substantially perfect crystalline configuration is resistant to oxidization and thereby remains unaffected. By suitably controlling the oxidization process, the density of the carbon nanotube fibers can be adjusted. The density of the carbon nanotube fibers may be in the order of 1,000 to 10¹² fibers/mm². The agent for the oxidization may also consist of gas containing oxygen at a prescribed partial pressure or heated nitric acid as well as atmosphere.

Thus, according to the present invention, a large number of metallic or alloy particles 3a can be formed by heating the metal or alloy in the catalytic layer 2 formed on the electroconductive member (electroconductive layer) 2 at a prescribed temperature while supplying inert gas. The carbon nanotube film 5 can be formed on the electroconductive member 2 in a favorable manner by growing carbon nanotube film 5 with the aid of the metallic or alloy particles 3a serving as a catalyst. For the formation of the carbon film, thermal CVD (which is also called as the chemical vapor deposition or chemical gas-phase growth method) was used in the foregoing embodiment, but other methods such as the microwave plasma method (plasma CVD), laser vapor deposition and sputtering can be also used.

When the carbon nanotube film 5 formed on the electroconductive member 2 as described above is used in a fuel cell, a catalyst such as platinum is deposited on the carbon nanotube film 5 and an electrolyte layer is placed thereon. Therefore, when the carbon nanotube film 5 is used in a fuel cell, the separator (inorganic substrate 1), electrode (electroconductive layer 2 and carbon nanotube film 5), platinum catalyst and electrolyte can be formed one over the other in a continuous matter and the interfaces between these layers can be formed highly neatly.

Therefore, as opposed to the conventional fuel cell, there is no need to apply an external force to the film/electrode assembly (MEA) by using threaded bolts or the like for the purpose of reducing the contact resistance on the surface of the electrode, and the interface resistance can be minimized in a stable manner. Because the interface resistance can be minimized both easily and reliably, the production management can be simplified and the productivity can be improved. Also, the elimination of the threaded bolts or other means for applying an external force allows the size of the fuel cell to be minimized.

Moreover, using the carbon nanotube film 5 in the fuel cell provides the following advantages. (1) The overall resistance of the fuel cell can be minimized because the carbon nanotube film can be formed as a thin film without any difficulty. (2) Because the hydrophobic property that is required for the oxygen electrode is produced on the surface of the carbon nanotube surface, the property of the fuel cell is prevented from being prematurely degraded by the clogging of the pores with water. (3) Because the carbon nanotube having a relatively high crystalline configuration is resistant to corrosion, the service life of the fuel cell can be extended. (4) Because the carbon nanotube is highly porous, it serves as an excellent gas diffusion layer which favorably permits transmission of gas such as hydrogen and oxygen and offers a large surface area for adequately promoting the reaction.

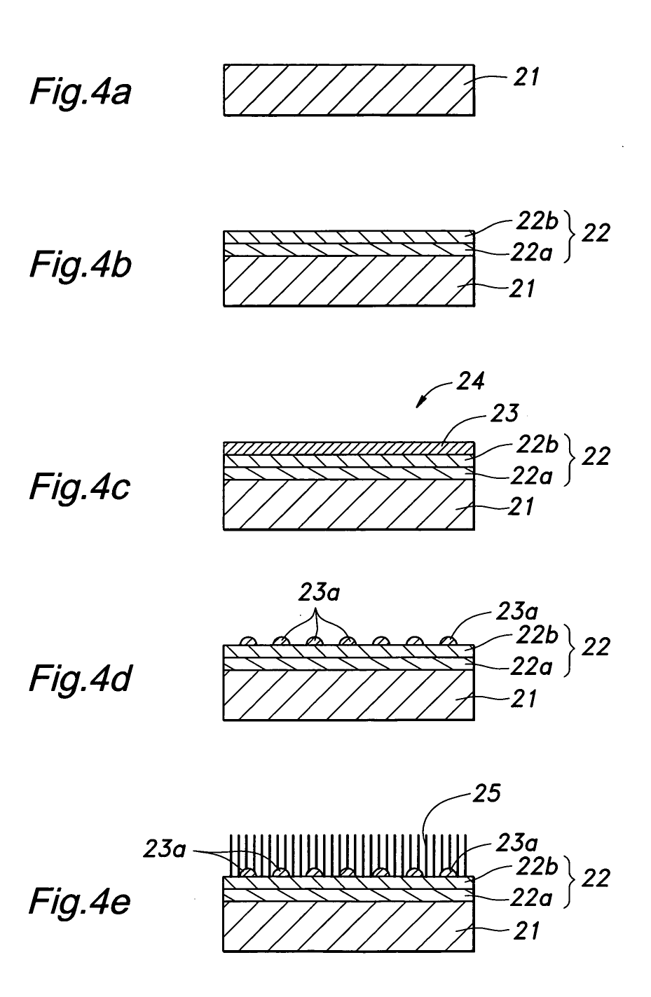

With reference to the schematic sectional view of FIG. 4, below describes a further embodiment of the method for forming a carbon nanotube according to the present invention. The device illustrated in FIG. 3 was used for the film forming process.

A silicon substrate 21 having a mirror finished surface is cleansed in sulfuric acid-hydrogen peroxide for 10 minutes, and then rinsed in water. The oxide film thereon is removed by using buffered hydrofluoric acid (MHF) and then dried (FIG. 4a). Titanium (Ti) film 22a is formed on the cleansed silicon substrate 21 to a thickness of 50 nm at the rate of 1 nm/sec under a pressure of 6×10⁻⁵ Pa by resistive heating vapor deposition, and tungsten (W) film 22b is formed thereon to a thickness of 100 nm under an Ar partial pressure of 5×10⁻³ Torr (6.7×10⁻⁴ Pa) by RF sputtering (FIG. 4b).

The RF sputtering is suited for forming film of material having a high melting point such as tungsten. The titanium (Ti) film 22a and tungsten (W) film 22b forms an electroconductive layer 22. Then, under a pressure of 1×10⁻⁴ Pa, iron (Fe) is deposited on the tungsten film 22b at the rate of 0.1 nm/sec to a thickness of 5 nm so as to form a catalytic layer 23 having a thickness of 5 nm (FIG. 4c). Electron beam vapor deposition is suited for forming film of material having a relatively low melting point such as iron.

The assembly having the electroconductive layer 22 and catalytic layer 23 formed on the silicon substrate 21 is secured to the quartz holder 14 placed in the quartz tube 12 in the thermal CVD device 10 shown in FIG. 3. The inner diameter of the quartz tube 12 is 30 mm. Helium gas is introduced into the quartz tube 12 at the flow rate of 230 sccm, and the temperature of the electric furnace 16 is set to approximately 700° C. When the temperature of the electric furnace 16 substantially reaches 700° C., the same temperature is maintained for to 30 minutes so that the iron 23 on the surface of the assembly turns into fine particles 23a (FIG. 4d).

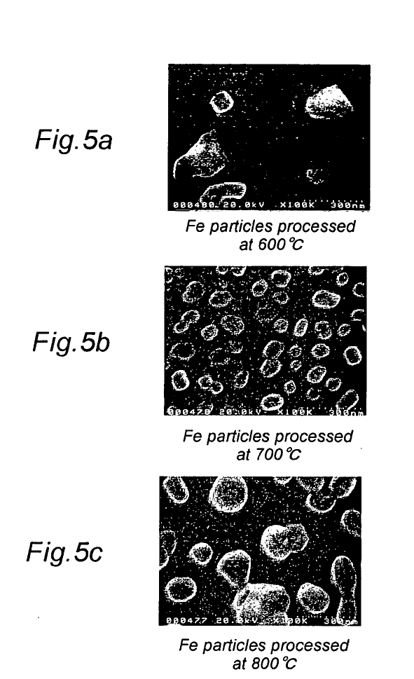

FIGS. 5a, 5b, and 5c are photographs that show the state of the iron particles 23a when the heating temperature was changed. As shown in FIG. 5a, when the heating temperature was 600° C. which is lower than 700° C., the iron did not adequately turn into fine particles. As shown in FIG. 5c, when the heating temperature was 800° C. which is higher than 700° C., the iron particles became coarse and failed to turn into adequately fine particles. According to the present embodiment, the iron on the surface turned into fine particles in an optimum fashion when the heating temperature was 700° C. Thus, according to the present invention, the heating temperature of 700° C. was most desirable in obtaining fine particles for the catalytic layer 23. On the other hand, as one skilled in the art will appreciate, how the catalytic metal turns into fine particles very much depends on the thickness of the catalytic layer 23, wettability of the lower electroconductive layer 22, configuration of the electroconductive layer 22 and heating time, and the optimum temperature may well depend on such factors.

After the iron of the catalytic layer 23 turns into small particles, acetylene (C₂H₂) is introduced into the tube at the flow rate of 30 sccm while the flow rate of helium is reduced to 200 sccm. After about fifteen minutes of processing, a multi-walled nanotube (MWNT) 25 having a thickness of approximately 30 μm is obtained (FIG. 4e). Thereafter, the supply of acetylene is terminated and the assembly is cooled to the room temperature by flowing helium. The assembly 24 having the MWNT 25 formed thereon is removed from the tube, and amorphous carbon is removed by processing the assembly in the atmosphere for five minutes at the temperature of 700° C. This produces a carbon nanotube structure having numerous gaps therein. The produced carbon nanotube consists of MWNT having a diameter in the range of 10 to 50 nm and the film is formed by fibers extending perpendicularly to the substrate.

Thus, according to the present invention, the metal or alloy of the catalytic layer can be turned into fine particles both easily and reliably by first forming the catalytic layer consisting of the metal or alloy serving as a catalyst for forming a carbon nanotube on an electroconductive member and then keeping it at a prescribed temperature while supplying inert gas, and the catalytic particles prepared in this manner allow the carbon nanotube to be formed on the electroconductive member in an efficient manner.

Although the present invention has been described in terms of preferred embodiments thereof, a person skilled in the art will readily recognize that various alterations and modifications are possible without departing from the scope of the present invention which is set forth in the appended claims.

1. A method for making a carbon nanotube on an electroconductive member, comprising the steps of:
forming a catalytic layer on the electroconductive member, wherein the catalytic layer consists of a metal or alloy capable of a catalytic action;
preprocessing the catalytic layer to turn the metal or alloy thereof into catalytic particles having a particle size of about 50 nm or less, wherein the preprocessing step comprises the step of heating the catalytic layer to a prescribed temperature for a prescribed period of time while supplying an inert gas at a prescribed velocity; and
growing a carbon nanotube on the electroconductive member by using the catalyst particles.

2. A method for making a carbon nanotube according to claim 1, wherein the catalytic layer comprises a member selected from a group consisting of Fe, Ni, Co, Mo and an alloy thereof.

3. A method for making a carbon nanotube according to claim 1, wherein the electroconductive member comprises at least one material selected from a group consisting of Ti, Au, Ni, Co, Cu, Al, Mo, W and Ta.

4. A method for making a carbon nanotube according to claim 1, wherein the inert gas consists of helium or argon.

5. A method for making a carbon nanotube according to claim 1, wherein the prescribed temperature is in a range of 0.49 Tm to 0.59 Tm, where Tm is the melting point of the metal or alloy of the catalytic layer in Kelvin.

6. A method for making a carbon nanotube according to claim 5, wherein the catalytic layer consists of iron and the prescribed temperature is approximately 700° C.

7. A method for making a carbon nanotube according to claim 1, wherein the catalytic particles have a particle size of about 0.5 nm to about 50 nm.

8. A method for making a carbon nanotube according to claim 1, wherein the step of growing the carbon nanotube comprises the step of supplying a mixed gas containing a hydrocarbon gas and an inert gas at a ratio of 1:2 to 1:50.

9. A method for making a carbon nanotube according to claim 8, wherein the step of supplying the mixed gas is conducted at a flow rate of 1 to 100 cm/min.

10. A method for making a carbon nanotube according to claim 9, wherein the step of supplying the mixed gas is conducted at a flow rate of approximately 30 cm/min.

11. A method for making a carbon nanotube according to claim 9, wherein the step of growing the carbon nanotube comprises the step of placing the electroconductive member including the catalytic particles in a tube having an inner diameter of approximately 30 mm, and flowing the mixed gas substantially along the length of the tube at a flow rate of 200 to 300 sccm (standard cubic centimeter per minute).

12. A method for making a carbon nanotube according to claim 1, wherein the electroconductive member comprises an inorganic substrate.

13. A carbon nanotube formed on an electroconductive member according to the method steps as set forth in claim 1.
